(19) United States
(12) Patent Application Publication
(10) Pub. No.: US 2004/0175874 A1
(43) Pub. Date: Sep. 9, 2004

(54) Manufacturing method of a semiconductor thin film using a solid laser beam

(75) Inventors: Hiroshi Matsumoto, Tokyo (JP); Shigeru Morikawa, Tokyo (JP); Toshio Kudo, Yokosuka-shi (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignees: Casio Computer Co., Ltd., Tokyo (JP); SUMITOMO HEAVY INDUSTRIES, LTD., Tokyo (JP)

(21) Appl. No.: 10/794,271

(22) Filed: Mar. 4, 2004

(30) Foreign Application Priority Data
Mar. 7, 2003 (JP) 2003-61438

(51) Int. Cl. H01L 21/00; H01L 21/84

(52) U.S. Cl. 438/166; 438/308

(57) ABSTRACT

A manufacturing method of a semiconductor thin film, comprising preparing a substrate, forming a semiconductor thin film on the substrate; and irradiating laser beam to the semiconductor thin film, wherein the semiconductor thin film is formed at a thickness so that an absorption rate to the laser beam is equal to or higher than 80% of a peak value, by using light interference that occurs in the interior of the semiconductor thin film, and the semiconductor thin film is crystallized or re-crystallized by irradiating the laser beam, is provided.

### BACKGROUND OF THE INVENTION

1. Field of the Invention

The present invention relates to a manufacturing method of a semiconductor thin film, for crystallizing or re-crystallizing a semiconductor thin film by using a solid laser beam.

2. Description of the Related Art

As a manufacturing method of a poly silicon thin film transistor, there is a method of using, for example XeCl excimer laser beam. By this method, an XeCl excimer laser beam is irradiated to an amorphous silicon thin film that is formed beforehand. The amorphous silicon thin film is crystallized by the irradiation of laser beam. By this, the amorphous silicon thin film becomes a poly silicon thin film. The poly silicon thin film is separated to many parts by element separation. The separated poly silicon thin film is used in forming multiple thin film transistors.

The above manufacturing method is disclosed in for example, Unexamined Japanese Patent Application KOKAI Publication No. H5-109771.

Recently, laser beams which are converted from solid laser by Second Harmonic Generation (SHG) are being considered instead of the XeCl excimer laser beam. The reasons for this are because solid laser has a more stable output, and maintenance thereof is easier as compared to XeCl excimer laser, therefore, the running cost is cheaper, and placing area of the device is smaller, etc.

FIG. 3 is an attribute diagram showing the relationship between the wavelength (unit: nm) of the laser beam irradiated to the amorphous silicon thin film and the light absorption rate (%) of the amorphous silicon thin film. In this attribute diagram, the curved line shown in dotted lines is an attribute curved line in a case where the thickness of the amorphous silicon thin film is set at an appropriate value, for example approximately 45 nm. Referring to the attribute curved line shown by the dotted line, in a case where the XeCl excimer laser beam with a wavelength of 308 nm is used, the light absorption rate exceeds 40%. In a case where an Nd:YLF/SHG laser beam with a wave length of for example 527 nm is used, the light absorption rate is lower than 30%. Therefore, in a case where a solid laser beam is used, amorphous silicon thin film can not be changed to poly silicon thin film by crystallization, unless laser energy (intensity) per unit area is set higher than a case where XeCl excimer laser is used.

In a case where a solid laser beam is used, the laser energy (intensity) per unit area can be set high, by making the size of the laser beam smaller by a homogenizer. However, if the size of the laser beam is made smaller, there is a problem that processing time necessary for crystallizing the substrate per unit area becomes longer, and that productivity decreases.

The content of Unexamined Japanese Patent Application No. H5-109771 is incorporated herein by reference in their entirety.

### SUMMARY OF THE INVENTION

An object of the present invention is to provide a manufacturing method of a semiconductor thin film that can maintain a substantial laser energy (intensity) per unit area, that is high enough for crystallization, even if the size of the laser beam is enlarged.

According to the present application, a manufacturing method of a semiconductor thin film, comprising: preparing a substrate; forming a semiconductor thin film on the substrate; and irradiating laser beam to the semiconductor thin film; wherein the semiconductor thin film is formed at a thickness so that an absorption rate to the laser beam is approximately at its peak, by light interference that occurs in the interior of the semiconductor thin film, and is crystallized or re-crystallized by irradiating the laser beam, is provided.

According to the present invention, the thickness of the semiconductor thin film is set so that the absorption rate to the laser beam is approximately at its peak, by using light interference that occurs therein. By this, the light absorption rate of the semiconductor thin film is high, and the semiconductor thin film can be crystallized, even if crystallization energy is reduced. Therefore, substantial laser energy (intensity) per unit area, high enough for crystallization, can be maintained, even if the size of the laser beam is enlarged.

### BRIEF DESCRIPTION OF THE DRAWINGS

This object and other objects and advantages of the present invention will become more apparent upon reading of the following detailed description and the accompanying drawings in which:

FIGS. 1A and 1B are diagrams for describing a manufacturing method of a semiconductor thin film as an embodiment of the present invention. FIG. 1A is a ross-sectional view of a situation where an amorphous silicon thin film is formed, and FIG. 1B is a cross-sectional view of a situation where a poly silicon thin film is formed by crystallization of the amorphous silicon thin film irradiated by solid laser.

FIG. 2 is a diagram showing light absorption rate of an amorphous silicon thin film in a case where the thickness of the amorphous silicon thin film is changed as a parameter.

FIG. 3 is a diagram showing the relationship between the light absorption rate of the amorphous silicon thin film and the wavelength of the laser beam to be irradiated.

FIG. 4 is a diagram showing light absorption rate of an amorphous silicon thin film in a case where the thickness of a second insulating film is changed as a parameter.

FIG. 5 is a diagram showing light absorption rate of an amorphous silicon thin film in a case where the thickness of a first insulating film is changed as a parameter.

FIG. 6 is a diagram showing light absorption rate of an amorphous silicon thin film in a case where the thickness of an upper insulating film formed on the amorphous silicon thin film is changed as a parameter.

FIG. 7 is a cross-sectional view of a main part of an example of liquid crystal display element manufactured by the manufacturing method applying the present invention.

FIG. 8 is a cross-sectional view for describing an initial process, when manufacturing the liquid crystal display element shown in FIG. 7.

FIG. 9 is a cross-sectional view for describing a process following the process of FIG. 8.

FIG. 10 is a cross-sectional view for describing a process following the process of FIG. 9.

FIG. 11 is a cross-sectional view for describing a process following the process of FIG. 10.

### DETAILED DESCRIPTION OF THE PREFERRED EMBODIMENT

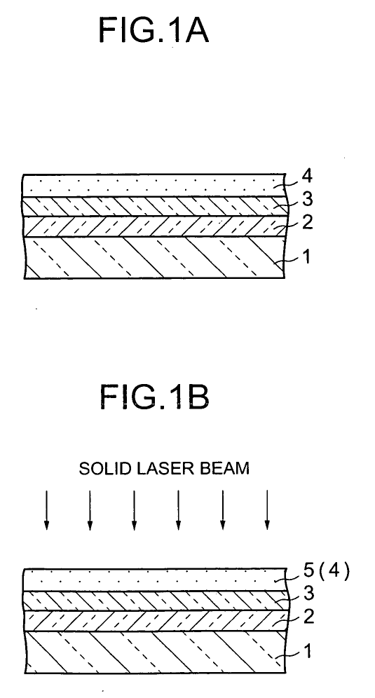

A manufacturing method of a semiconductor thin film as an embodiment of the present invention will be described with reference to FIGS. 1A and 1B. As shown in FIG. 1A, on a top surface of a glass substrate 1 heated to approximately 350° C., a first underlying insulating film 2 made of silicon nitride, a second underlying insulting film 3 made of silicon oxide, and an amorphous silicon thin film (a semiconductor thin film) 4 are sequentially formed by plasma CVD (Chemical Vapor Deposition) method.

To eliminate hydrogen from the amorphous silicon thin film 4 that has a high hydrogen content, and is formed by the plasma CVD method, dehydrogenation processing of approximately 450° C. and approximately two hours, is carried out in nitrogen gas atmosphere. In the latter process, when high energy is provided to the amorphous silicon thin film 4 by irradiation of a solid laser beam, defects occur in the amorphous silicon thin film 4, by sudden activity of the hydrogen. Dehydrogenation processing is carried out in order to prevent the defects to occur.

Next, as shown in FIG. 1B, solid laser beam is irradiated as will be later described, to the amorphous silicon thin film 4. By this, the amorphous silicon thin film 4 is crystallized, and becomes a poly silicon thin film 5.

Here, experiment results will be described. In an experiment, the thickness of the first underlying insulating film 2 is set to 200 nm, and the thickness of the second underlying insulating film 3 is set to 100 nm. The thickness of the amorphous silicon thin film 4 is a parameter. The refractive index of the glass substrate 1 is set to 1.52, the refractive index of the first underlying insulating film 2 is set to 1.89, the refractive index of the second underlying insulating film 3 is set to 1.46, and the refractive index of the amorphous silicon thin film 4 is set to 4.20. It is assumed that there is no light absorption by the glass substrate 1, the first underlying insulating film 2 and the second underlying insulating film 3, and that there is light absorption only by the amorphous silicon thin film 4. The quenching coefficient (extinction coefficient) of the amorphous silicon thin film 4 is assumed to be 0.42.

Nd:YLF (Yttrium Lithium Fluoride)/SHG (pulse oscillation, wavelength 527 nm) laser beam, which is converted from Nd:YLF laser beam by second harmonic generation, is used as the solid laser beam. A beam irradiation region of the amorphous silicon thin film 4 is scanned by the Nd:YLF/SHG laser beam. At this time, the pulse of the Nd:YLF/SHG laser is irradiated on the amorphous silicon thin film 4 at an overlapping rate of 90%. Irradiating at an overlapping rate of 90% means irradiating, shifting the pulse of he laser beam by 10% of the width thereof, to the width direction of the laser beam. amely, in a same region of the amorphous silicon thin film 4, a pulsed laser beam is irradiated 10 times.

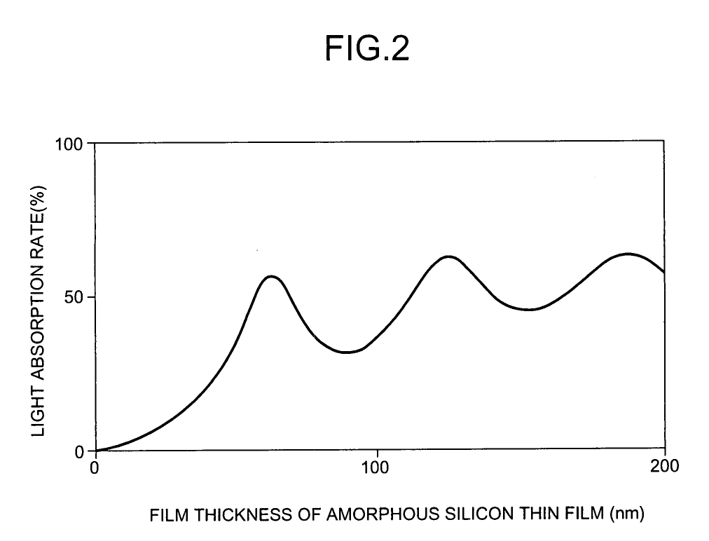

The relationship between the thickness of the amorphous silicon thin film 4 and the light absorption rate of the amorphous silicon thin film 4 to the Nd:YLF/SGH laser beam is examined. By this examination, the results shown in FIG. 2 is obtained. As apparent from FIG. 2, the peaks of the light absorption rate appear in a case where the film thickness is approximately 62 nm, approximately 125 nm, and approximately 187 nm, mainly due to light interference that occurs in the amorphous silicon thin film 4.

On the other hand, the thickness of the amorphous silicon thin film, wherein the peaks of the light absorption, which are caused by light interference in the film, appear, are obtained by the next expression (1). However, d is the film thickness of the amorphous silicon thin film, k is 1,2,3 . . . , λ is the wavelength of the laser beam, and n is the refractive index of the amorphous silicon thin film.

d=k×λ/2n (1)

In the expression (1), when λ=527 nm, n=4.20, k=1, 2, 3 are substituted, the thickness d of the amorphous silicon thin film becomes approximately 63 nm (62 nm in FIG. 2), approximately 125 nm (125 nm in FIG. 2), and approximately 188 nm (187 nm in FIG. 2). Therefore, in a case where the Nd:YLF/SHG (pulse oscillation, wavelength 527 nm) laser beam is used, it is preferable that for example, the thickness of the amorphous silicon thin film is approximately 62 nm.

Next, an invention sample applying the present invention, and comparison sample for comparing therewith are prepared. In the invention sample, the thickness of the first underlying insulating film 2 is set to approximately 200 nm, the thickness of the second underlying insulating film 3 is set to approximately 100 nm, and the thickness of the amorphous silicon film 4 is set to approximately 62 nm. In the comparison sample, the thickness of the first and second underlying insulating films 2 and 3 are set at the same thickness as the invention sample, and the thickness of the amorphous silicon thin film 4 is set thinner than that in the invention sample, for example, approximately 45 nm.

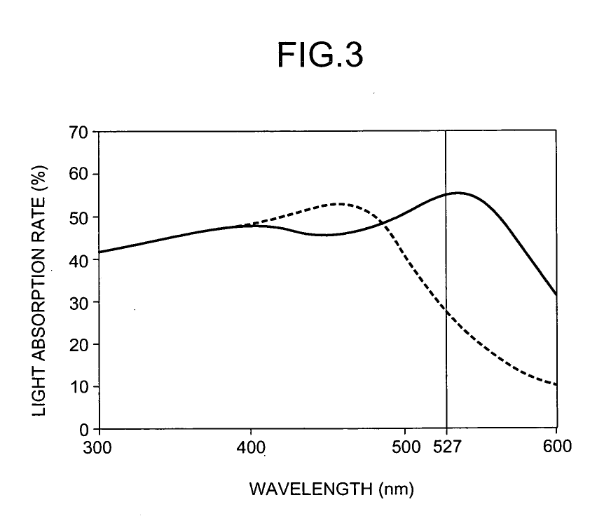

The relationship between the light absorption rate of the amorphous silicon thin film 4 and the laser wave length, after the dehydrogenation processing, is examined. By this examination, results shown in FIG. 3 are obtained. In FIG. 3, the solid line indicates absorption spectrum of the invention sample, and the dotted line indicates absorption spectrum of the comparison sample. As apparent from FIG. 3, the light absorption rate to the wave length 527 nm is approximately 54% in the case of the invention sample indicated by the solid line, and is approximately 28% in the case of the comparison sample indicated by the dotted line.

In a case where the light absorption rate of the amorphous silicon thin film that has a thickness of 45 nm, to the laser beam with a wavelength of 527 nm, is 28%, according to Lambert-Beer's Law, the light absorption rate of the amorphous silicon thin film with a thickness of 62 nm is only supposed to be 36%. However, the light absorption rate of the amorphous silicon thin film that constitutes the invention sample, is 54%, and is larger than 36%. This difference is apparently underlyingd on the light absorption rate increasing by the light interference that occurs in the amorphous silicon thin film 4.

With reference to FIG. 3, in a case of an XeCl excimer laser with a wavelength of 308 nm, the absorption rate when the thickness of the amorphous silicon thin film 4 is 5 nm, indicated by the dotted line, is completely the same as when the amorphous silicon thin film 4 is 62 nm, indicated by the solid line. Namely, it can be understood that there is no increase in light absorption rate by light interference in the amorphous silicon thin film 4.

In a case where the thickness of the amorphous silicon thin film 4 is 45 nm, indicated by the dotted line, the light absorption rate shows a peak, wherein the wavelength is approximately 460 nm, and when the wavelength exceeds this, the rate gradually decreases. On the other hand, in a case where the thickness of the amorphous silicon thin film 4 is 62 nm, indicated by the solid line, even if the wavelength exceeds 460 nm, the light absorption rate gradually increases until the wavelength is approximately 530 nm. Therefore, in a case where the wavelength is equal to or more than approximately 460 nm, it can be understood that the rate of increase of the light absorption rate caused by light interference in the amorphous silicon thin film 4 is significant. When obtaining, using expression (1), the thickness of the amorphous silicon thin film 4, wherein the light absorption rate is maximum, in a case where the wavelength is 460 nm, it is 55 nm when k=1, 110 nm when k=2, and 164 nm when k=3.

Next, energy density of the Nd:YLF/SHG (pulse oscillation, wavelength 527 nm) laser beam, will be described. In FIG. 3, as described above, the light absorption rate in a case where the wavelength of the laser beam is 527 nm, is 28% when the thickness of the amorphous silicon thin film 4 is 45 nm, and 54% when the thickness of the amorphous silicon thin film 4 is 62 nm. Therefore, in a case where solid laser beam is irradiated, the energy density thereof obviously can be decreased, in accordance with the light absorption rate. For example, an energy density necessary to form a poly silicon thin film 5, wherein the average of a crystal grain diameter is equal to or more than 0.3 μm, is approximately 950 mJ/cm² in a case of an amorphous silicon thin film 4 of a comparison sample, having a thickness of approximately 45 nm, and is approximately 500 mJ/cm², which is approximately half of the case of the comparison sample, in a case of an amorphous silicon thin film 4 of an invention sample, having a thickness of 62 nm. In case of the invention sample, the thickness of the amorphous silicon thin film 4 is set at 62 nm, so that the light absorption rate is 54%, which is high. Therefore, to set the crystal grain diameter of the poly silicon thin film 5 to an average of equal to or larger than 0.3 μm, the energy density of the laser beam to the invention sample can be set at approximately half as in the case of the comparison sample. In other words, in the case of the invention sample, a poly silicon thin film 5 wherein the crystal grain diameter has an average of equal to or larger than 0.3 μm, can be obtained, even if the energy density of the laser beam is set at approximately half as in the case of the comparison sample.

As above, when the thickness of the amorphous silicon thin film 4 is set at 62 nm, which is a thickness where the absorption rate to the laser beam becomes the peak by the light interference that occurs therein, the light absorption rate of the amorphous silicon thin film 4 becomes 54%, which is high. Therefore, even if the energy of the laser beam is decreased, it is possible to form a polycrystalline thin film by crystallizing the amorphous silicon thin film 4. Therefore, even if the laser bean size is made larger, laser energy per unit area, for crystallization can be highly maintained. Consequently, increase of processing time necessary to crystallize one substrate, can be suppressed, and high productivity can be maintained.

The solid laser beam may be a laser beam having a wavelength in the vicinity of 530 nm, which is Nd:YAG (Yttrium Aluminum Garnet)/SHG (pulse oscillation, wavelength 532 nm), Nd:YVO4 (Yttrium Orthovanadate or Yttrium Vanadium tera Oxide)/SHG (pulse oscillation, wavelength 532 nm), Nd:YVO4/SHG (continuous oscillation, wavelength 532 nm), etc., generated by second harmonic generation, other than the above described Nd:YLF/SHG (pulse oscillation, wavelength 527 nm). In this case, it is not limited to total solid (DPSS: Diode Pumped Solid State) laser beam, and solid laser beam of lamp excitation may be used. Gas laser beam such as Argon laser beam (continuous oscillation, wavelength 458 nm to 515 nm) etc., may be used. Furthermore, it is not limited to second harmonic generation, and a solid laser having a wavelength of equal to or more than 300 nm, generated by a third harmonic generation, may be used.

If the thickness of the amorphous silicon thin film 4 is in a range of approximately±10% of the film thickness obtained from for example the above described expression (1), (63 nm, 125 nm, 188 nm, . . . ), a high light absorption rate of approximately 80 to 90% of the above described peak value can be obtained. Therefore, the thickness of the amorphous silicon thin film 4 may be set in the range of approximately±10% of the film thickness obtained from for example the above described expression (1). In short, in a case where a solid laser beam having a wavelength of approximately equal to or more than 460 nm is irradiated, it may be set so that light absorption rate increases by light interference in the amorphous silicon thin film 4, which can not be obtained in a case where an excimer laser is irradiated.

Furthermore, the underlying insulating film may be only the second underlying insulating film 3 made of silicon oxide. Moreover, the amorphous silicon thin film 4 may be directly formed on the top surface of the glass substrate 1, without the underlying insulating film being provided.

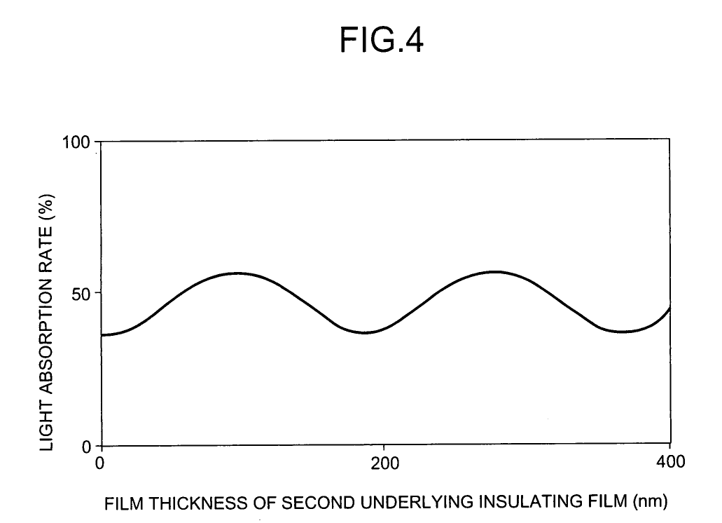

In a case where the thickness of the first underlying insulating film 2 is set to approximately 200 nm, the thickness of the amorphous silicon thin film 4 is set to approximately 62 nm, and the thickness of the second underlying insulating film 3 is a parameter, the relationship between the light absorption rate of the amorphous silicon thin film 4 and the thickness of the second underlying insulating film 3 is examined. By this examination, the results shown in FIG. 4 is obtained. As apparent from FIG. 4, peaks of light absorption appear when the film thickness is approximately 96 nm and approximately 277 nm. In FIG. 4, the variation of the light absorption rate of the amorphous silicon thin film 4 to the thickness of the second underlying insulating film 3 is not large. Therefore, if the thickness of the second underlying insulating film 3 is in a range of±50 nm (50 to 150 nm, or 230 to 330 nm) the thickness where the peak of the light absorption appears, a high light absorption rate of approximately 80% of the peak value can be obtained. Therefore, the above described effect can be obtained by setting the thickness in the range, in a case of practical use.

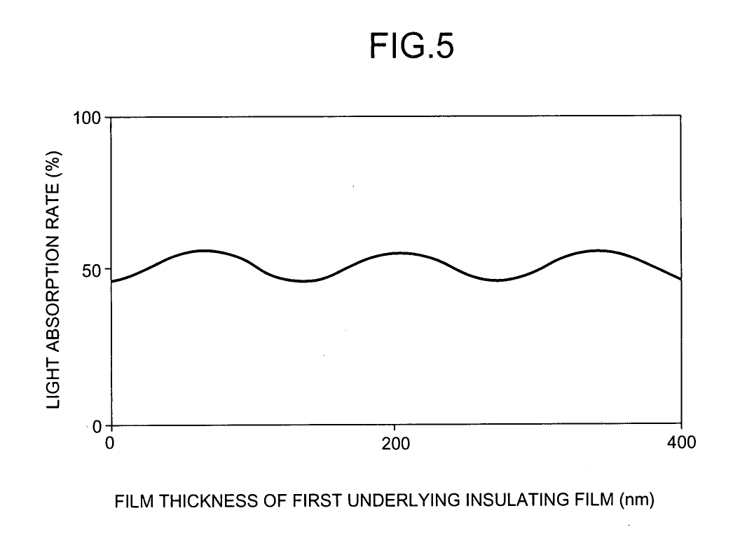

In a case where the thickness of the second underlying insulating film 3 is set to approximately 100 nm, the thickness of the amorphous silicon thin film 4 is set to approximately 62 nm, and the thickness of the first underlying insulating film 2 is a parameter, the relationship between the light absorption rate of the amorphous silicon thin film 4 and the thickness of the first underlying insulating film 2 is examined. By this examination, the results shown in FIG. 5 are obtained. As apparent from FIG. 5, peaks of light absorption appear in a case where the film thickness is approximately 64 nm, approximately 203 nm, and approximately 343 nm. In FIG. 5, the variation of the light absorption rate of the amorphous silicon thin film 4 to the thickness of the first underlying insulating film 2 is not large. Therefore, if the thickness of the first underlying insulating film 2 is in a range of±20 nm (44 to 84 nm, 183 to 223 nm, 323 to 363 nm) of the thickness where the peak of the light absorption appears, a high light absorption rate of approximately 90% of the peak value can be obtained. Therefore, the above described effect can be obtained by setting the film thickness in the range, in a case of practical use.

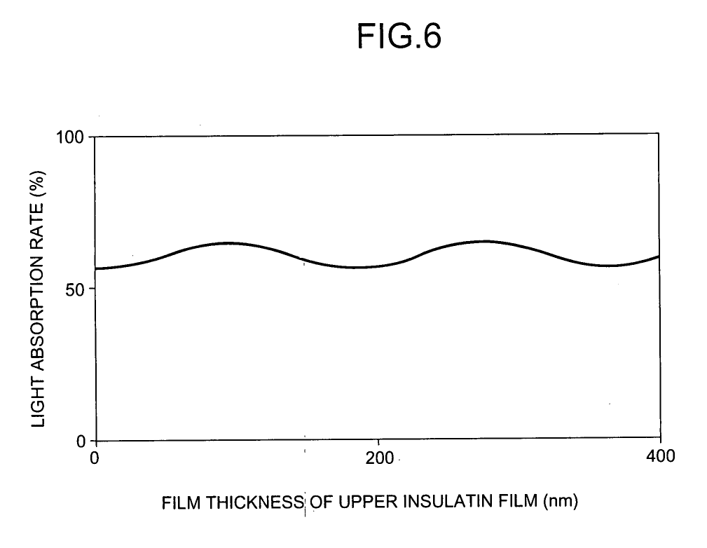

Further, in a case where the thickness of the first insulating film 2 is set to approximately 200 nm, the second underlying insulating film 3 is set to approximately 100 nm, and the thickness of the amorphous silicon thin film 4 is set to approximately 62 nm, and an upper layer insulating film (not shown) made of silicon oxide is formed on the top surface of the amorphous silicon thin film 4, and thickness of the upper layer insulating film is a parameter, the relationship between the light absorption rate of the amorphous silicon thin film 4 and the thickness of the upper layer insulating film is examined. By this examination, the results shown in FIG. 6 are obtained. As apparent from FIG. 6, peaks of light absorption rate appear in a case where the film thickness is approximately 93 nm, and approximately 273 nm. In FIG. 6, variation of the light absorption rate of the amorphous silicon thin film 4 to the thickness of the upper layer insulating film is not large. Therefore, if the thickness of the upper layer insulating film is in a range of±65 nm (28 to 158 nm, 208 to 338 nm) of the thickness where the peak of the light absorption appears, a high light absorption rate of approximately 90% of the peak value can be obtained. Therefore, the above described effect can be obtained by setting the film thickness in the range, in a case of practical use.

Here, concrete numeric will be omitted, but even in a case where there aren't underlying insulating films, or even in a case where either one of the first underlying insulating film 2 or second underlying insulating film 3 is formed, it is possible to set the thickness of each film so that the absorption rate to the laser beam becomes approximately at a peak, under a predetermined condition.

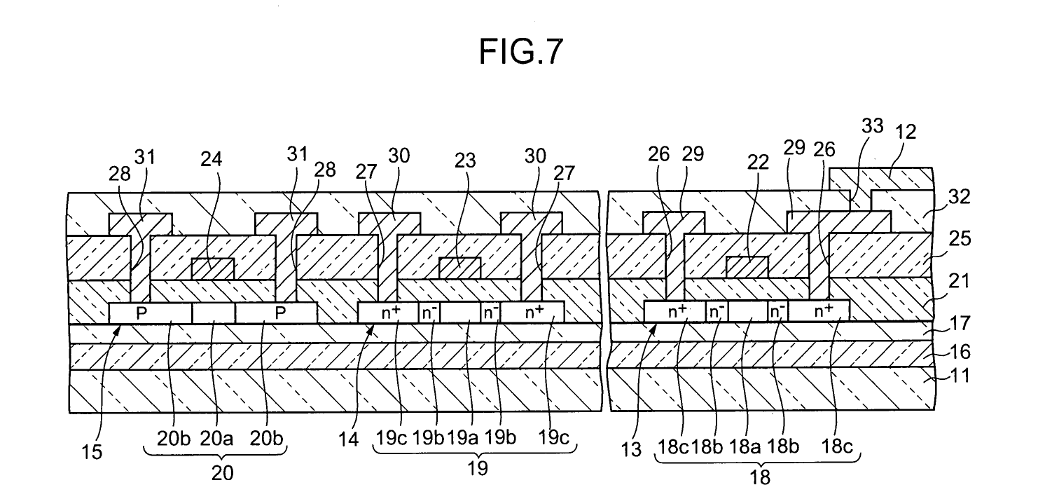

FIG. 7 shows a cross-sectional diagram of a main part of liquid crystal display element manufactured by a manufacturing method applying the present invention. In the liquid crystal display element, in a forming region for a pixel circuit unit on a glass substrate 11, a pixel electrode 12 and an NMOS thin film transistor 13 connected to the pixel electrode 12 are provided. In a forming region for a peripheral driving circuit unit on the glass substrate 11, a CMOS thin film transistor comprising an NMOS thin film transistor 14 and a PMOS thin film transistor 15 is provided.

Each of the thin film transistors 13, 14, and 15 comprise poly silicon thin films 18, 19, and 20, which are provided at predetermined portions on first and second underlying insulating films 16 and 17, which are provided on the glass substrate 11. In this case, The NMOS thin film transistors 13 and 14 have an LDD (Lightly Doped Drain) structure.

Namely, center parts of poly silicon thin films 18 and 19 which structure the NMOS thin film transistors 13 and 14, are channel regions 18a and 19a which comprise intrinsic regions, and both sides thereof are source drain regions 18b and 19b which comprise n-type impurities low concentration regions, wherein the concentration of the n-type impurities is low, and further, both sides thereof are source drain regions 18c and 19c comprising n-type high concentration regions, wherein the concentration of the n-type impurities is high. On the other hand, a center part of a poly silicon thin film 20 that structures the PMOS thin film transistor 15 is a channel region 20a which comprises an intrinsic region, and both sides thereof are source drain regions 20b comprising p-type impurity high concentration regions, wherein the concentration of the p-type impurity is high.

On the top surfaces of the second underlying insulating film 17, the poly silicon thin films 18, 19, and 20, a gate insulating film 21 is provided. In predetermined portions, which correspond to channel regions 18a, 19a, and 20a, of the top surface of the gate insulating film 21, gate electrodes 22, 23, and 24 are respectively provided. On the top surfaces of the gate insulating film 21, the gate electrodes 22, 23, and 24, an interlayer insulating film 25 is provided.

Contact holes 26 are provided to the interlayer insulating film 25 and the gate insulating film 21, so as to reach the source drain regions 18c of the poly silicon thin film 18. Contact holes 27 are provided to the interlayer insulating film 25 and the gate insulating film 21, so as to reach the source drain regions 19c of the poly silicon thin film 19. Contact holes 28 are provided to the interlayer insulating film 25 and the gate insulating film 21, so as to reach the source drain regions 20b of the poly silicon thin film 20.

Source drain electrodes 29, 30, and 31 are respectively provided in the contact holes 26, 27, and 28, and predetermined portions, which are near the contact holes 26, 27, and 28, of the top surface of the interlayer insulating film 25. On the top surfaces of the interlayer insulating film 25, the source drain electrodes 29, 30, and 31, an over coat film 32 is provided. On a predetermined portion in the top surface of the overcoat film 32, a pixel electrode 12 is provided. The pixel electrode 12 is connected to either one of the source drain electrodes 29 that constitutes the NMOS thin film transistor 13, via a contact hole 33 provided at a predetermined portion of the overcoat film 32.

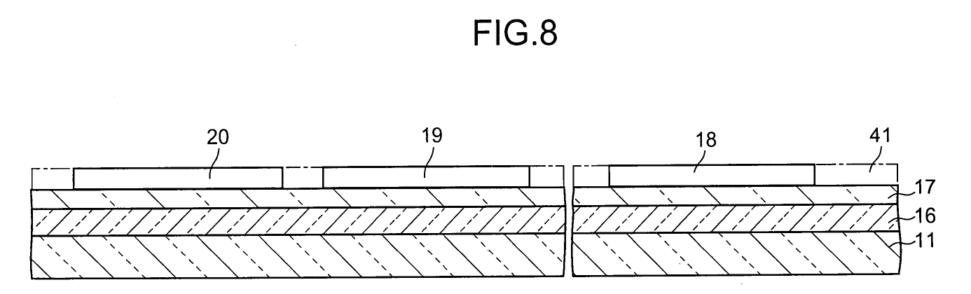

Next, an embodiment of a manufacturing method of the liquid crystal display element that has the above structure will be described. First, as shown in FIG. 8, on the top surface of the glass substrate 11 heated to approximately 350° C., a first underlying insulating film 16 made of silicon nitride, a second underlying insulating film 17 made of silicon oxide, and an amorphous silicon thin film 41 are sequentially formed. In this case, the thickness of the first underlying insulating film 16 is set to approximately 200 nm, and the thickness of the second underlying insulating film 17 is set to approximately 100 nm. The thickness of the amorphous silicon thin film 41 is set at for example, approximately 62 nm, which is a thickness, where the absorption rate to the laser beam becomes a peak by light interference that occurs therein.

To eliminate hydrogen from the amorphous silicon thin film 41 that has a high hydrogen content, and is formed by a plasma CVD method, dehydrogenation processing of approximately 450° C. and approximately two hours, is carried out in nitrogen gas atmosphere. In the latter process, when high energy is provided to the amorphous silicon thin film 41 by irradiation of a solid laser beam, defects occur in the amorphous silicon thin film 41 by sudden activity of the hydrogen. Dehydrogenation processing is carried out in order to prevent this kind of defects to occur.

The energy density of the total solid (DPSS) Nd:YLF/SHG (pulse oscillation, wavelength 527 nm) laser beam is set to approximately 500 mJ/cm². Then, the laser beam irradiates the beam irradiation region of the amorphous silicon thin film 41 with an overlapping rate equal to or higher than 90%. By this, the beam irradiation region of the amorphous silicon thin film 41 is scanned by the laser beam. As a result, the amorphous silicon thin film 41 is crystallized, and becomes a polysilcon thin film. By patterning the poly silicon thin film, poly silicon thin films 18, 19, and 20 are formed in predetermined portions of the top surface of the second insulating film 17.

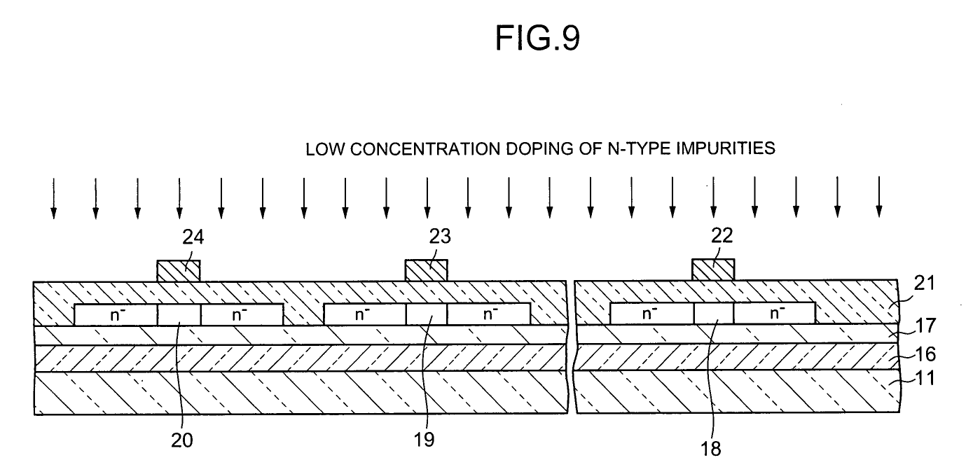

As shown in FIG. 9, on the top surfaces of the second underlying insulating film 17, poly silicon thin films 18, 19, and 20, a gate insulating film 21 made of silicon oxide is formed in a thickness of approximately 1000 Å (100 nm), by a plasma CVD method. Then, an Mo film having a thickness of approximately 3000 Å (300 nm), is formed on the top surface of the gate insulating film 21 by a spatter method. By patterning the Mo film, gate electrodes 22, 23, and 24 are formed in predetermined portions, which are placed at the center parts of the poly silicon films 18, 19, and 20, of the top surface of the gate insulating film 21.

The gate electrodes 22, 23, and 24 are used as masks, and n-type impurities are doped at a low concentration. For example, phosphorus ions are doped with a condition of acceleration energy 70 keV, dose amount 1×10¹³ atm/cm². By this, in predetermined regions, which correspond to both sides of the gate electrodes 22, 23, and 24, of the poly silicon thin films 18, 19, and 20, n-type impurities low concentration regions are respectively formed.

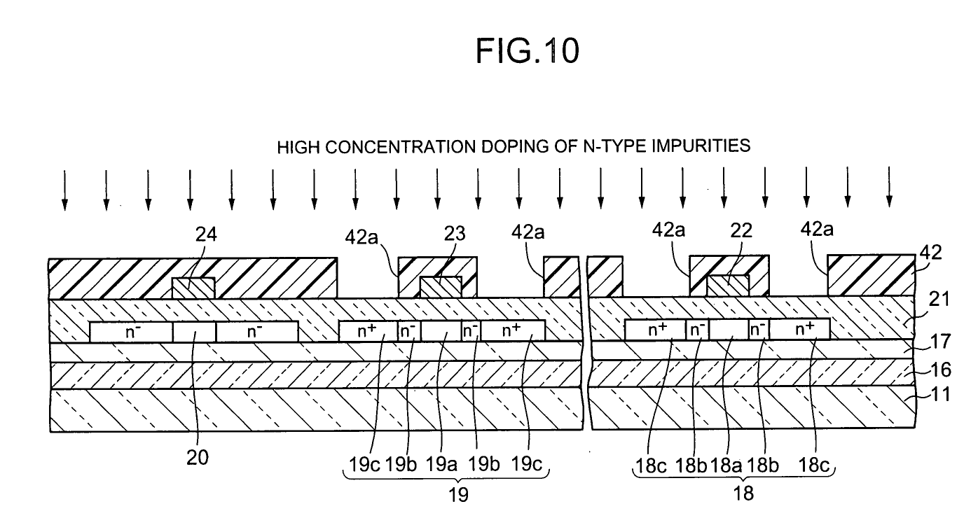

As shown in FIG. 10, on the top surfaces of the gate insulating film 21, gate electrodes 22, 23, and 24, a resist pattern 42, which has openings 42a in portions corresponding to forming regions for n-type impurities high concentration regions 18c and 19c of the poly silicon thin films 18 and 19, is formed. The resist pattern 42 is used as a mask, and n-type impurities are doped at a high concentration. For example, phosphorus ions are doped with a condition of acceleration energy 70 keV, dose amount 1×10¹⁵ atm/cm². By this, channel regions 18a and 19a made of intrinsic regions are formed in predetermined regions, which exist under the gate electrodes 22 and 23, of the poly silicon thin films 18 and 19, source drain regions 18b and 19b made of n-type impurities low concentration regions are formed on both sides thereof, and source drain regions 18c and 19c made of n-type impurities high concentration regions are further formed on both sides thereof respectively. Then, the resist pattern 42 is detached.

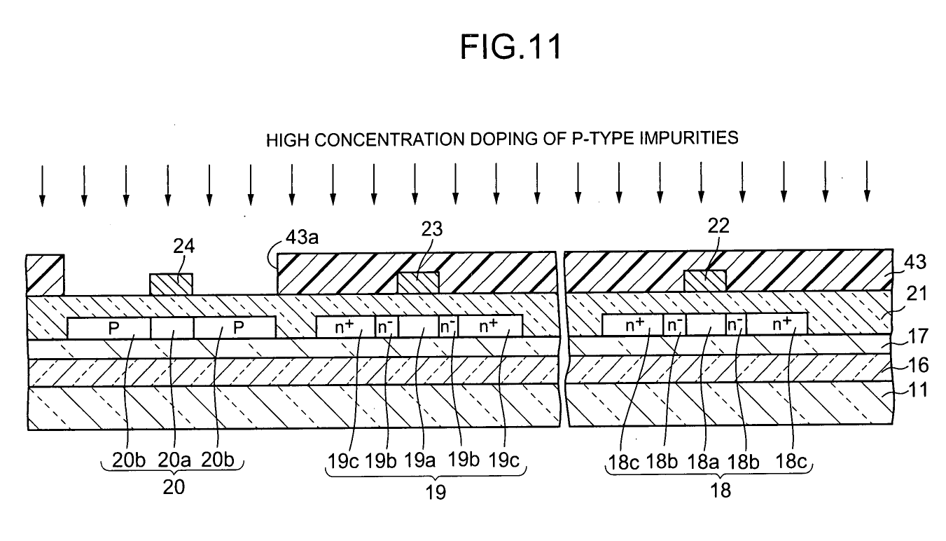

Next, as shown in FIG. 11, on the top surfaces of the gate insulating film 21, gate electrodes 22 and 23, a resist pattern 43 which has an opening 43a over the poly silicon thin film 20, is formed. The resist pattern 43 and the gate electrode 24 are used as masks, and p-type impurities are doped at a high concentration. For example, boron ions are doped with a condition of acceleration energy 30 keV, dose amount 1×10¹⁵ atm/cm². By this, a channel region 20a made of an intrinsic region is formed in a predetermined region, which exists under the region of the gate electrode 24, of the poly silicon thin film 20, and a source drain region 20b made of p-type impurities high concentration region are formed on both sides thereof. Then, the resist pattern 43 is detached.

Activation of the doped impurities is carried out by annealing processing at approximately 500° C. and for approximately one hour, in nitrogen gas atmosphere. This activation may be carried out after the forming process of source drain electrodes, which ill be later described.

As shown in FIG. 7, on the top surfaces of the gate insulating film 21, gate electrodes 22, 23, and 24, an interlayer insulating film 25 made of silicon nitride is formed in a thickness of approximately 4000 Å (400 nm), by a plasma CVD method. Then, contact holes 26 are formed to the interlayer insulating film 25 and the gate insulating film 21, so as to reach the source drain regions 18c of the poly silicon thin film 18. Contact holes 27 are formed to the interlayer insulating film 25 and the gate insulating film 21, so as to reach source drain regions 19c of the poly silicon thin film 19. Further, contact holes 28 are formed to the interlayer insulating film 25 and the gate insulating film 21, so as to reach the source drain regions 20b of the poly silicon thin film 20.

An Al film having a thickness of approximately 5000 Å (500 nm), and an Mo film for ITO contact, having a thickness of approximately 500 Å (50 nm), are sequentially formed in the contact holes 26, 27, and 28, and on predetermined portions which are near the contact holes 26, 27, and 28, of the top surface of the interlayer insulating film 25. By pattering the Al film and the Mo film, source drain electrodes 29, 30, and 31 are respectively formed in the contact holes 26, 27, and 28, in the predetermined portions of the top surface of the interlayer insulating film 25. Then, an overcoat film 32 made of silicon nitride is formed on the top surfaces of the interlayer insulating film 25, source drain electrodes 29, 30, and 31, by a plasma CVD method.

Then, a contact hole 33 is formed to a predetermined portion of the overcoat film 32, so as to reach either of source drain electrodes 29. An ITO film having a thickness of approximately 500 Å is formed on the top surface of the overcoat film 32, by a spatter method. By pattering the ITO film, a pixel electrode 12 that is connected via a contact hole 33 to either one of the source drain electrodes 29 that constitute the NMOS thin film transistor 13, is formed in the predetermined portion of the top surface of the overcoat 32. In this way, the liquid crystal display element shown in FIG. 7 can be obtained.

In the above embodiment, a case where, after n-type impurities are doped at a high concentration, as shown in FIG. 10, and p-type impurities are doped at a high concentration, as shown in FIG. 11 are described. However, it may be opposite to this. That is, after p-type impurities are doped at a high concentration, as shown in FIG. 11, n-type impurities may be doped at a high concentration, as shown in FIG. 10.

In the above embodiment, a case where the NMOS thin film transistor has an LDD structure is described. However, it may be opposite to this. That is, the present invention can be applied to a case where a PMOS thin film transistor has an LDD structure. The present invention can also be applied to a case where both the NMOS thin film transistor and the PMOS thin film transistor have an LDD structure. Furthermore, the present invention is not limited to the active matrix type liquid crystal display element, and may be widely applied to other elements such as an active matrix type organic EL (electroluminescent) display device, etc.

As described above, according to the present invention, the thickness of the amorphous semiconductor thin film is set so that the absorption rate to the laser beam is approximately at its peak, by using light interference that occurs therein. Namely, the light absorption rate of the amorphous semiconductor thin film is high. Therefore, even if the crystallization energy of the laser beam is set low, it is possible to form a poly crystal thin film by crystallizing the amorphous semiconductor thin film. Consequently, a substantially high laser beam energy (intensity) per unit area, necessary for crystallization can be maintained, even if the laser beam size is enlarged. Therefore, processing time necessary for crystallizing a substrate per unit area can be reduced, and productivity can be improved.

Various embodiments and changes may be made thereunto without departing from he broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the resent invention.

This application is based on Japanese Patent Application No. 2003-61438 filed on Mar. 7, 2003, and including specification, claims, drawings and summary. The disclosure of the above Japanese Patent Application is incorporated herein by reference in its entirety.

What is claimed is:

1. A manufacturing method of a semiconductor thin film, comprising:
preparing a substrate;
forming a semiconductor thin film on said substrate; and
irradiating laser beam to said semiconductor thin film; wherein
said semiconductor thin film is formed at a thickness so that an absorption rate to the laser beam is equal to or higher than 80% of a peak value, by light interference that occurs in the interior of the semiconductor thin film, and is crystallized or re-crystallized by irradiating the laser beam.

2. The manufacturing method of the semiconductor thin film according to claim 1, further including forming an insulating film on the substrate, before the semiconductor thin film is formed, wherein the insulating film is formed at a thickness so that the absorption rate to the laser beam is equal to or higher than 90% of the peak value.

3. The manufacturing method of the semiconductor thin film according to claim 1, further including forming a first insulating film on the substrate, before the semiconductor thin film is formed, and forming a second insulating film on the first insulating film, before the semiconductor thin film is formed, wherein
at least either of the first insulating film or the second insulating film is formed at a thickness so that the absorption rate to the laser beam is equal to or higher than 90% of the peak value.

4. The manufacturing method of the semiconductor thin film according to claim 1, further including forming an upper layer insulating film on the semiconductor thin film, before the laser beam is irradiated to the semiconductor thin film, wherein said upper layer insulating film is formed at a thickness so that the absorption rate to the laser beam is equal to or higher than 90% of the peak value.

5. The manufacturing method of the semiconductor thin film according to claim 1, herein said laser beam is a solid laser beam with a wavelength equal to or longer than 458 nm.

6. The manufacturing method of the semiconductor thin film according to claim 1, wherein said semiconductor thin film is formed at a thickness so that the absorption rate to the laser beam is equal to or higher than 90% of the peak value, by using light interference that occurs in the interior of the semiconductor thin film.

7. The manufacturing method of the semiconductor thin film according to claim 1, wherein said laser beam is converted from a solid laser beam by a second harmonic generation.

8. The manufacturing method of the semiconductor thin film according to claim 1, wherein said laser beam is a total solid laser beam.

9. The manufacturing method of the semiconductor thin film according to claim 1, wherein said laser beam is converted from a total solid laser beam by a second harmonic generation.

10. The manufacturing method of the semiconductor thin film according to claim 1, wherein said laser beam has a wavelength of approximately 530 nm, in a visible range, being converted from a total solid laser beam by a second harmonic generation.

11. The manufacturing method of the semiconductor thin film according to claim 10, wherein said laser beam is either Nd:YLF/SHG (pulse oscillation, wavelength 527 nm), Nd:YAG/SHG (pulse oscillation, wavelength 532 nm), Nd:YVO4/SHG (pulse oscillation, wavelength 532 nm), and Nd:YVO4/SHG (continuous oscillation, wavelength 532 nm).

12. The manufacturing method of the semiconductor thin film according to claim 1, wherein said laser beam is argon laser beam.

13. The manufacturing method of the semiconductor thin film according to claim 1, wherein irradiating said laser beam comprises scanning the semiconductor thin film by the laser beam, overlapping the irradiation region of the laser beam.

14. The manufacturing method of the semiconductor thin film according to claim 1, wherein irradiating the laser beam comprises irradiating the laser beam at an overlapping rate equal to or higher than 90%.

15. The manufacturing method of the semiconductor thin film according to claim 1, wherein the semiconductor thin film formed on the substrate, is an amorphous semiconductor thin film.

16. The manufacturing method of the semiconductor thin film according to claim 15, wherein irradiating the laser beam comprises crystallizing the amorphous semiconductor thin film, by irradiating laser beam to said semiconductor thin film.
